(19) United States
(12) Patent Application Publication
(10) Pub. No.: US 2021/0408099 A1
(43) Pub. Date: Dec. 30, 2021

(54) IMAGING DEVICE

(71) Applicant: Panasonic Intellectual Property Management Co., Ltd., Osaka (JP)

(72) Inventor: YOSHIHIRO SATO, Osaka (JP)

(21) Appl. No.: 17/474,521

(22) Filed: Sep. 14, 2021

Related U.S. Application Data
(63) Continuation of application No. PCT/JP2020/016235, filed on Apr. 13, 2020.

(30) Foreign Application Priority Data
Apr. 26, 2019 (JP) 2019-086530
Mar. 27, 2020 (JP) 2020-058613

(51) Int. Cl. H01L 27/146

(52) U.S. Cl. CPC H01L 27/14638; H01L 27/14621; H01L 27/14645; H01L 27/1461

(57) ABSTRACT

An imaging device includes pixels. Each of the pixels includes a first photoelectric conversion layer that converts light into first electric charge, a first pixel electrode that collects the first electric charge, a second photoelectric conversion layer that is arranged above the first photoelectric conversion layer and that converts light into second electric charge, and a second pixel electrode that collects the second electric charge. The area of the first pixel electrode is smaller than the area of the second pixel electrode.

### BACKGROUND

### 1. Technical Field

The present disclosure relates to an imaging device.

### 2. Description of the Related Art

Imaging devices using photoelectric conversion have hitherto been widely used.

International Publication No. 2016/002576 discloses an imaging device including multiple photoelectric converters that are laminated.

### SUMMARY

In one general aspect, the techniques disclosed here feature an imaging device including pixels. Each of the pixels includes a first photoelectric conversion layer that converts light into first electric charge, a first pixel electrode that collects the first electric charge, a second photoelectric conversion layer that is arranged above the first photoelectric conversion layer and that converts light into second electric charge, and a second pixel electrode that collects the second electric charge. The area of the first pixel electrode is smaller than the area of the second pixel electrode.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a configuration diagram of an imaging apparatus according to a first embodiment of the present disclosure;

FIG. 2A is a cross-sectional view of an imaging device illustrated in FIG. 1;

FIG. 2B is a cross-sectional view of an imaging device having another configuration of multiple counter electrodes;

FIG. 2C is a cross-sectional view of an imaging device having another configuration of the multiple counter electrodes;

FIG. 3A is a diagram illustrating how pixel electrodes and plugs are arranged when the imaging device according to the first embodiment is viewed from a normal direction of a semiconductor substrate;

FIG. 3B is a diagram illustrating another arrangement of the pixel electrodes when the imaging device according to the first embodiment is viewed from the normal direction of the semiconductor substrate;

FIG. 4A is a cross-sectional view of an imaging device according to a first modification;

FIG. 4B is a cross-sectional view of another imaging device according to the first modification;

FIG. 5 is a cross-sectional view of an imaging device according to a second modification;

FIG. 6A is a cross-sectional view of an imaging device according to a third modification;

FIG. 6B is a diagram illustrating how a first charge accumulation region, a second charge accumulation region, a third charge accumulation region, and a first pixel electrode are arranged when the imaging device according to the third modification is viewed from the normal direction of the semiconductor substrate;

FIG. 6C is a diagram illustrating another arrangement of the first charge accumulation region, the second charge accumulation region, the third charge accumulation region, and the first pixel electrode when the imaging device according to the third modification is viewed from the normal direction of the semiconductor substrate;

FIG. 7A is a cross-sectional view of an imaging device according to a second embodiment;

FIG. 7B is a diagram illustrating how the pixel electrodes and the plugs are arranged when the imaging device according to the second embodiment is viewed from the normal direction of the semiconductor substrate;

FIG. 8 is a cross-sectional view of an imaging device according to a third embodiment;

FIG. 9 is a diagram illustrating how the pixel electrodes and photodiodes are arranged when the imaging device according to the third embodiment is viewed from the normal direction of the semiconductor substrate; and

FIG. 10 is a cross-sectional view of an imaging device according to a fourth embodiment.

### DETAILED DESCRIPTION

### (Underlying Knowledge Forming Basis of the Present Disclosure)

The inventors have conducted an in-depth review of the cause to prevent an improvement of the quality of images generated by an imaging device disclosed in International Publication No. 2016/002576. As a result, the inventors have found the following problem.

With the imaging device disclosed in International Publication No. 2016/002576, color mixture caused by light that is obliquely incident is likely to cause a problem. In other words, the light that is obliquely incident on a certain pixel is also incident on an adjacent pixel to cause the color mixture between the pixels. Suppression of the color mixture caused by the light that is obliquely incident is beneficial to the improvement of the image quality.

The present disclosure provides a technique to suppress the color mixture caused by the light that is obliquely incident.

### (Summary of One Aspect According to the Present Disclosure)

An imaging device according to a first aspect of the present disclosure includes pixels.

Each of the pixels includes
a first photoelectric conversion layer that converts light into first electric charge,
a first pixel electrode that collects the first electric charge,
a second photoelectric conversion layer that is arranged above the first photoelectric conversion layer and that converts light into second electric charge, and
a second pixel electrode that collects the second electric charge.

The area of the first pixel electrode is smaller than the area of the second pixel electrode.

According to the first aspect, even when the light is obliquely incident on a certain pixel, the electric charge occurring in the oblique incidence is less likely to be collected in the first pixel electrode because the area of the first pixel electrode is restricted. As a result, the color mixture between the adjacent pixels may be suppressed.

In a second aspect of the present disclosure, for example, the imaging device according to the first aspect may further include a semiconductor substrate. The first pixel electrode may be within an outer edge of the second pixel electrode when the imaging device is viewed from a normal direction of the semiconductor substrate. With this configuration, it is possible to suppress the color mixture caused by the oblique incidence more sufficiently.

In a third aspect of the present disclosure, for example, in the imaging device according to the first or second aspect, the material of the first pixel electrode may be different from the material of the second pixel electrode. With this configuration, photoelectric conversion caused by the incidence of light on the semiconductor substrate may be suppressed to reduce parasitic sensitivity.

In a fourth aspect of the present disclosure, for example, in the imaging device according to any of the first to third aspects, the first pixel electrode may be thicker than the second pixel electrode. With this configuration, the photoelectric conversion caused by the incidence of light on the semiconductor substrate may be further suppressed to reduce the parasitic sensitivity.

In a fifth aspect of the present disclosure, for example, the imaging device according to any of the first to fourth aspects may further include a semiconductor substrate; a first charge accumulation region that is provided in the semiconductor substrate and that is electrically connected to the first pixel electrode; and a second charge accumulation region that is provided in the semiconductor substrate and that is electrically connected to the second pixel electrode. The first charge accumulation region and the second charge accumulation region may be overlapped with the first pixel electrode when the imaging device is viewed from a normal direction of the semiconductor substrate. With this configuration, since the light is blocked by the first pixel electrode, the light is less likely to be incident on each charge accumulation region.

In a sixth aspect of the present disclosure, for example, the imaging device according to any of the first to fifth aspects may further include a third photoelectric conversion layer that is arranged between the first photoelectric conversion layer and the second photoelectric conversion layer and that converts light into third electric charge and a third pixel electrode that collects the third electric charge. This configuration is suitable for formation of a full-color image.

In a seventh aspect of the present disclosure, for example, in the imaging device according to the sixth aspect, the area of the third pixel electrode may be smaller than the area of the second pixel electrode. With this configuration, the electric charge occurring in the oblique incidence is less likely to be collected in the second pixel electrode because the area of the second pixel electrode is restricted. As a result, the color mixture between the adjacent pixels may be suppressed.

In an eighth aspect of the present disclosure, for example, in the imaging device according to the sixth or seventh aspect, the area of the first pixel electrode may be smaller than the area of the third pixel electrode. With this configuration, both the advantageous effect achieved when the area of the first pixel electrode is smaller than the area of the second pixel electrode and the advantageous effect achieved when the area of the third pixel electrode is smaller than the area of the second pixel electrode are achieved.

In a ninth aspect of the present disclosure, for example, the imaging device according to any of the sixth to eighth aspects may further include a semiconductor substrate. The third pixel electrode may be within an outer edge of the second pixel electrode when the imaging device is viewed from a normal direction of the semiconductor substrate. With this configuration, it is possible to suppress the color mixture caused by the oblique incidence more sufficiently.

In a tenth aspect of the present disclosure, for example, the imaging device according to any of the sixth to ninth aspects may further include a semiconductor substrate. The first pixel electrode may be within an outer edge of the third pixel electrode when the imaging device is viewed from a normal direction of the semiconductor substrate. With this configuration, both the advantageous effect achieved when the first pixel electrode is within the outer edge of the second pixel electrode and the advantageous effect achieved when the third pixel electrode is within the outer edge of the second pixel electrode are achieved.

In an eleventh aspect of the present disclosure, for example, in the imaging device according to any of the sixth to tenth aspects, the material of the first pixel electrode may be different from the material of the third pixel electrode. With this configuration, the photoelectric conversion caused by the incidence of light on the semiconductor substrate may be further suppressed to reduce the parasitic sensitivity.

In a twelfth aspect of the present disclosure, for example, in the imaging device according to any of the sixth to eleventh aspects, the first pixel electrode may be thicker than the third pixel electrode. With this configuration, the photoelectric conversion caused by the incidence of light on the semiconductor substrate may be further suppressed to reduce the parasitic sensitivity.

In a thirteenth aspect of the present disclosure, for example, the imaging device according to any of the sixth to twelfth aspects may further include a semiconductor substrate, a first charge accumulation region that is provided in the semiconductor substrate and that is electrically connected to the first pixel electrode, a second charge accumulation region that is provided in the semiconductor substrate and that is electrically connected to the second pixel electrode, and a third charge accumulation region that is provided in the semiconductor substrate and that is electrically connected to the third pixel electrode. The first charge accumulation region, the second charge accumulation region, and the third charge accumulation region may be overlapped with the first pixel electrode when the imaging device is viewed from a normal direction of the semiconductor substrate. With this configuration, since the light is blocked by the first pixel electrode, the light is less likely to be incident on each charge accumulation region.

In a fourteenth aspect of the present disclosure, for example, the imaging device according to any of the sixth to thirteenth aspects may further include a semiconductor substrate. The distance between an outer edge of the first pixel electrode and an outer edge of the third pixel electrode may be longer than the distance between an outer edge of the second pixel electrode and the outer edge of the third pixel electrode in a direction parallel to a surface of the semiconductor substrate. With this configuration, it is possible to significantly suppress the color mixture caused by the oblique incidence.

In a fifteenth aspect of the present disclosure, for example, in the imaging device according to any of the first to fourteenth aspects, a part of the first photoelectric conversion layer in a first pixel arbitrarily selected from the pixels may be electrically connected to a part of the first photoelectric conversion layer in a pixel adjacent to the first pixel, among the pixels. A part of the second photoelectric conversion layer in a second pixel arbitrarily selected from the pixels may be electrically connected to a part of the second photoelectric conversion layer in a pixel adjacent to the second pixel, among the pixels. In the fifteenth aspect of the present disclosure, for example, in the imaging device according to any of the first to fourteenth aspects, the plurality of pixels may include a first pixel, a second pixel, a third pixel adjacent to the first pixel, and a fourth pixel adjacent to the second pixel. A part of the first photoelectric conversion layer in a first pixel may be electrically connected to a part of the first photoelectric conversion layer in the third pixel, and a part of the second photoelectric conversion layer in a second pixel may be electrically connected to a part of the second photoelectric conversion layer in the fourth pixel. Application of the technique of the present disclosure to such a structure achieves the advantageous effect to suppress the color mixture more sufficiently.

An imaging device according to a sixteenth aspect of the present disclosure includes

a semiconductor substrate; and

pixels.

Each of the pixels includes
a first photoelectric conversion layer that is arranged above the semiconductor substrate,
a first pixel electrode that is electrically connected to the first photoelectric conversion layer and that collects electric charge corresponding to light in a first wavelength region,
a first charge accumulation region that is provided in the semiconductor substrate and that is electrically connected to the first pixel electrode,
a second photoelectric conversion layer that is arranged above the first photoelectric conversion layer,
a second pixel electrode that is electrically connected to the second photoelectric conversion layer and that collects electric charge corresponding to light in a second wavelength region, and
a second charge accumulation region that is provided in the semiconductor substrate and that is electrically connected to the second pixel electrode.

Both the first charge accumulation region and the second charge accumulation region are overlapped with the first pixel electrode when the imaging device is viewed from a normal direction of the semiconductor substrate.

According to the sixteenth aspect, since the light is blocked by the first pixel electrode, the light is less likely to be incident on each charge accumulation region. As a result, it is possible to reduce the parasitic sensitivity of the semiconductor substrate.

In a seventeenth aspect of the present disclosure, for example, the imaging device according to any of the first to sixteenth aspects may further include a semiconductor substrate. The first pixel electrode may include a first storage electrode that stores the first electric charge in the first photoelectric conversion layer and a first readout electrode that is electrically connected to the semiconductor substrate. The second pixel electrode may include a second storage electrode that stores the second electric charge in the second photoelectric conversion layer and a second readout electrode that is electrically connected to the semiconductor substrate.

Embodiments of the present disclosure will herein be described with reference to the drawings. The present disclosure is not limited to the following embodiments.

### First Embodiment

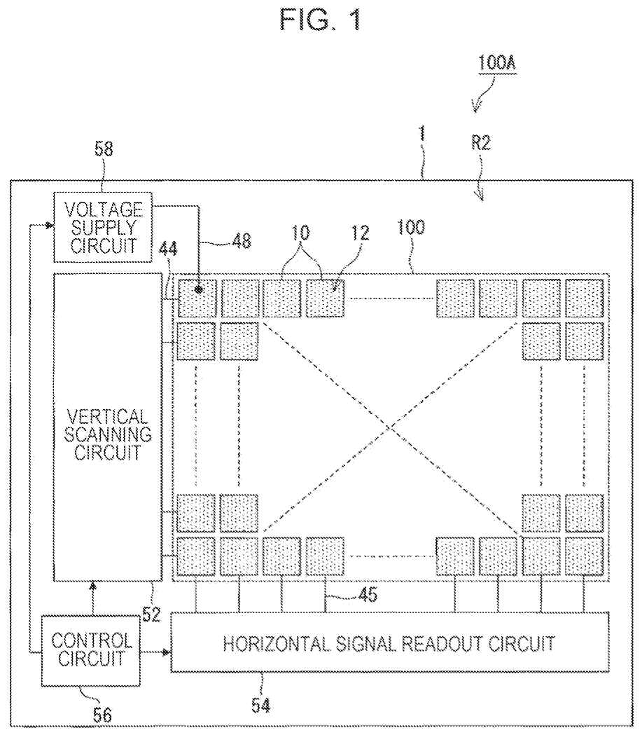

FIG. 1 illustrates the configuration of an imaging apparatus 100A according to a first embodiment of the present disclosure. The imaging apparatus 100A includes an imaging device 100. The imaging device 100 includes a semiconductor substrate 1 and multiple pixels 10. The multiple pixels 10 are provided on the semiconductor substrate 1. The respective pixels 10 are supported by the semiconductor substrate 1. Part of the pixels 10 may be composed of the semiconductor substrate 1.

The semiconductor substrate 1 may be a circuit board including various electronic circuits. The semiconductor substrate 1 is composed of, for example, a Si substrate.

Each pixel 10 includes a photoelectric converter 12. The photoelectric converter 12 generates positive electric charge and negative electric charge, typically, a pair of hole and electron in response to incident light. The photoelectric converter 12 includes at least one photoelectric conversion layer arranged above the semiconductor substrate 1. The photoelectric converters 12 of the respective pixels 10 are spatially separated in FIG. 1 for convenience of description. The photoelectric converters 12 of the multiple pixels 10 may be continuously arranged on the semiconductor substrate 1 with no space therebetween.

Referring to FIG. 1, the pixels 10 are aligned in multiple rows and multiple columns, specifically, in m-number rows and n-number columns. Here, m and n each independently represents an integer of one or more. The pixels 10 are, for example, two-dimensionally aligned on the semiconductor substrate 1 to form an imaging area. In a plan view of the imaging apparatus 100A, the imaging device 100 may be defined as an area where the photoelectric conversion layers exist.

The number and the arrangement of the pixels 10 are not particularly restricted. The center of each pixel 10 is positioned on a grip point of a square grip in FIG. 1. The multiple pixels 10 may be arranged so that the center of each pixel 10 is positioned on the grid point of a triangle grid, a hexagonal grid, or the like. The imaging device 100 may be used as a line sensor by one-dimensionally aligning the pixels 10.

The imaging apparatus 100A includes peripheral circuits formed on the semiconductor substrate 1.

The peripheral circuits include a vertical scanning circuit 52 and a horizontal signal readout circuit 54. The peripheral circuits may additionally include a control circuit 56 and a voltage supply circuit 58. The peripheral circuits may further include a signal processing circuit, an output circuit, and so on. The respective circuits are provided on the semiconductor substrate 1. Part of the peripheral circuits may be arranged on another substrate different from the semiconductor substrate 1 on which the pixels 10 are formed.

The vertical scanning circuit 52 is also referred to as a row scanning circuit. An address signal line 44 is provided for each row composed of the multiple pixels 10 and the address signal lines 44 are connected to the vertical scanning circuit 52. The signal line provided for each row composed of the multiple pixels 10 is not limited to the address signal line 44 and multiple kinds of signal lines may be connected to the vertical scanning circuit 52 for the respective rows each composed of the multiple pixels 10. The horizontal signal readout circuit 54 is also referred to as a column scanning circuit. A vertical signal line 45 is provided for each column composed of the multiple pixels 10 and the vertical signal lines 45 are connected to the horizontal signal readout circuit 54.

The control circuit 56 controls the entire imaging apparatus 100A in response to instruction data, a clock signal, and so on supplied from the outside of the imaging apparatus 100A. Typically, the control circuit 56 includes a timing generator and supplies a driving signal to the vertical scanning circuit 52, the horizontal signal readout circuit 54, the voltage supply circuit 58, and so on. The control circuit 56 may be realized by a microcontroller including one or more processors. The function of the control circuit 56 may be realized through a combination of a general-purpose processing circuit with software or may be realized by hardware dedicated to such processing.

The voltage supply circuit 58 supplies a certain voltage to each pixel 10 via a voltage line 48. The voltage supply circuit 58 is not limited to a certain power supply circuit and may be a circuit that converts voltage supplied from a power supply, such as a battery, into the certain voltage or a circuit that generates the certain voltage. The voltage supply circuit 58 may be part of the vertical scanning circuit 52 described above. These circuits composing the peripheral circuits may be arranged in a peripheral area R2 outside the imaging device 100.

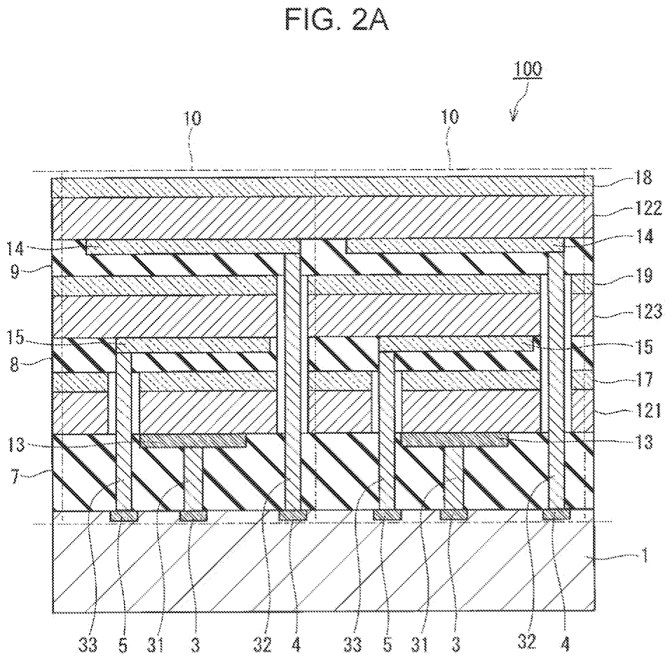

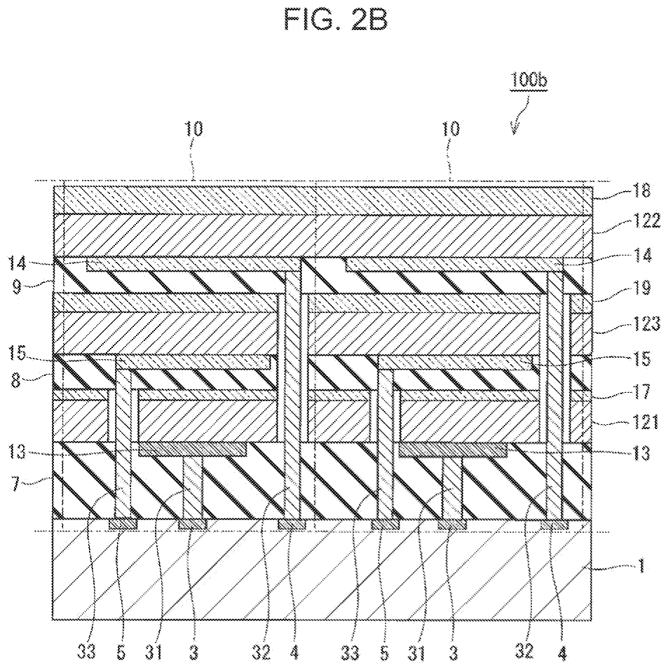

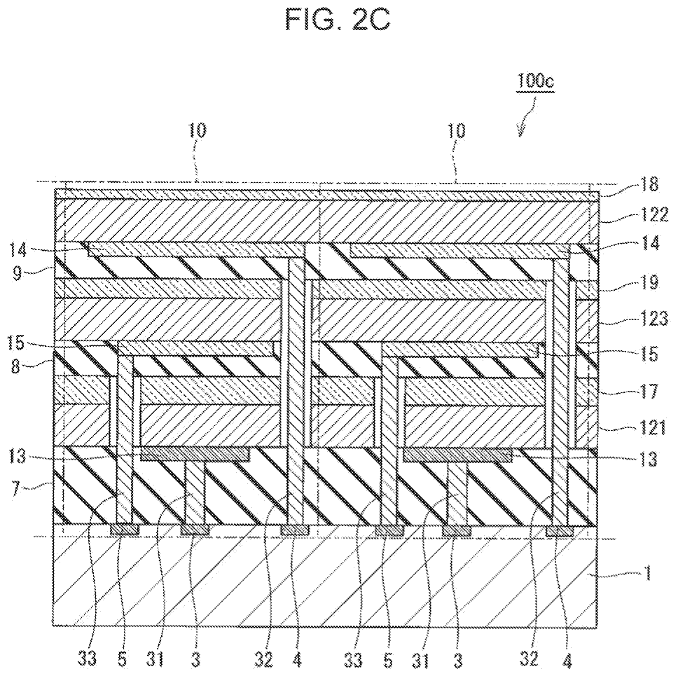

FIG. 2A illustrates a cross section of the imaging device 100.

Each pixel 10 includes multiple photoelectric conversion layers 121, 122, and 123. The multiple photoelectric conversion layers 121, 122, and 123 include a first photoelectric conversion layer 121, a second photoelectric conversion layer 122, and a third photoelectric conversion layer 123. The first photoelectric conversion layer 121 may be a single layer shared between the multiple pixels 10. The second photoelectric conversion layer 122 may be a single layer shared between the multiple pixels 10. The third photoelectric conversion layer 123 may be a single layer shared between the multiple pixels 10. However, each of the photoelectric conversion layers 121, 122, and 123 may be isolated for each pixel. The “sharing between the multiple pixels” means sharing between a certain pixel and at least one pixel adjacent to the certain pixel.

Color mixture caused by oblique incidence is likely to occur when each of the photoelectric conversion layers 121, 122, and 123 is a single layer, compared with the case in which each of the photoelectric conversion layers 121, 122, and 123 is isolated for each pixel. Accordingly, the technique of the present disclosure can produce a particularly high advantageous effect when each of the photoelectric conversion layers 121, 122, and 123 is a single layer.

The following structure may be adopted regardless of whether the case in which each of the photoelectric conversion layers 121, 122, and 123 is a single layer or the case in which each of the photoelectric conversion layers 121, 122, and 123 is isolated for each pixel is supposed. The first photoelectric conversion layer 121 in a certain pixel and the first photoelectric conversion layer 121 in the pixel adjacent to the certain pixel are electrically connected to each other. The second photoelectric conversion layer 122 in a certain pixel and the second photoelectric conversion layer 122 in the pixel adjacent to the certain pixel are electrically connected to each other. The third photoelectric conversion layer 123 in a certain pixel and the third photoelectric conversion layer 123 in the pixel adjacent to the certain pixel are electrically connected to each other. In other words, a part of the first photoelectric conversion layer 121 in a certain pixel 10 (a first pixel) arbitrarily selected from the multiple pixels 10 is electrically connected to a part of the first photoelectric conversion layer 121 in the pixel 10 adjacent to the certain pixel 10, among the multiple pixels 10. A part of the second photoelectric conversion layer 122 in a certain pixel 10 (a second pixel) arbitrarily selected from the multiple pixels 10 is electrically connected to a part of the second photoelectric conversion layer 122 in the pixel 10 adjacent to the certain pixel 10, among the multiple pixels 10. A part of the third photoelectric conversion layer 123 in a certain pixel 10 (a third pixel) arbitrarily selected from the multiple pixels 10 is electrically connected to a part of the third photoelectric conversion layer 123 in the pixel 10 adjacent to the certain pixel 10, among the multiple pixels 10. Application of the technique of the present disclosure to such a structure achieves the advantageous effect to suppress the color mixture more sufficiently.

The photoelectric conversion layers 121, 122, and 123 are made of a photoelectric conversion material. The photoelectric conversion material is typically an organic material.

The first photoelectric conversion layer 121 collects electric charge (first electric charge) corresponding to light in a first wavelength region. The second photoelectric conversion layer 122 collects electric charge (second electric charge) corresponding to light in a second wavelength region. The third photoelectric conversion layer 123 collects electric charge (third electric charge) corresponding to light in a third wavelength region. The first wavelength region is, for example, the wavelength region of red light. The first photoelectric conversion layer 121 is made of a material having the sensitivity to red light. The second wavelength region is, for example, the wavelength region of blue light. The second photoelectric conversion layer 122 is made of a material having the sensitivity to blue light. The third wavelength region is, for example, the wavelength region of green light. The third photoelectric conversion layer 123 is made of a material having the sensitivity to green light.

In the first embodiment, the semiconductor substrate 1, the first photoelectric conversion layer 121, the third photoelectric conversion layer 123, and the second photoelectric conversion layer 122 are layered in this order. The first photoelectric conversion layer 121 is arranged above the semiconductor substrate 1. The third photoelectric conversion layer 123 is arranged above the first photoelectric conversion layer 121. The second photoelectric conversion layer 122 is arranged above the third photoelectric conversion layer 123. In the normal direction of the semiconductor substrate 1, the first photoelectric conversion layer 121 is arranged between the third photoelectric conversion layer 123 and the semiconductor substrate 1. In the normal direction of the semiconductor substrate 1, the third photoelectric conversion layer 123 is arranged between the second photoelectric conversion layer 122 and the first photoelectric conversion layer 121. The order of layering of the photoelectric conversion layers 121, 122, and 123 is not limited to this order. Since the photoelectric conversion material absorbing blue light generally has low sensitivity, the layer having the sensitivity to blue light is advantageously used as a top layer.

In this specification, “upper” and “lower” are determined based on the traveling direction of light. The side closer to a light incident plane is referred to as the “upper” side and the side away from the light incident plane is referred to as the “lower” side.

Each pixel 10 further includes multiple pixel electrodes 13, 14, and 15. The multiple pixel electrodes 13, 14, and 15 include a first pixel electrode 13, a second pixel electrode 14, and a third pixel electrode 15. The first pixel electrode 13 is electrically connected to the first photoelectric conversion layer 121. The second pixel electrode 14 is electrically connected to the second photoelectric conversion layer 122. The third pixel electrode 15 is electrically connected to the third photoelectric conversion layer 123.

The second pixel electrode 14 and the third pixel electrode 15 are transparent electrodes having light transmittance to visible light and/or near-infrared light. The transparent electrode is made of a transparent conductive oxide, such as indium tin oxide (ITO). The first pixel electrode 13 is a non-transparent electrode that does not have light transmittance to the visible light and/or the near-infrared light. The material of the non-transparent electrode is, for example, metal, metal oxide, metal nitride, or conductive polysilicon.

In this specification, “having the light transmittance” means that the transmittance of light of a certain wavelength region is higher than or equal to 40%. The wavelength region of the visible light is, for example, 400 nm to 780 nm. The wavelength region of the near-infrared light is, for example, 780 nm to 2,000 nm. The transmittance can be calculated using a method defined in Japanese Industrial Standards JIS R3106 (1998).

Each pixel 10 further includes multiple counter electrodes 17, 18, and 19. The multiple counter electrodes 17, 18, and 19 include a first counter electrode 17, a second counter electrode 18, and a third counter electrode 19. Each of the counter electrodes 17, 18, and 19 may be a transparent electrode having the light transmittance to the visible light and/or the near-infrared light.

The first counter electrode 17 is provided for the first pixel electrode 13. The first photoelectric conversion layer 121 is sandwiched between the first counter electrode 17 and the first pixel electrode 13. The second counter electrode 18 is provided for the second pixel electrode 14. The second photoelectric conversion layer 122 is sandwiched between the second counter electrode 18 and the second pixel electrode 14. The third counter electrode 19 is provided for the third pixel electrode 15. The third photoelectric conversion layer 123 is sandwiched between the third counter electrode 19 and the third pixel electrode 15. The first counter electrode 17 is electrically connected to the first photoelectric conversion layer 121. The second counter electrode 18 is electrically connected to the second photoelectric conversion layer 122. The third counter electrode 19 is electrically connected to the third photoelectric conversion layer 123.

The first counter electrode 17 may be a single layer shared between the multiple pixels 10. The second counter electrode 18 may be a single layer shared between the multiple pixels 10. The third counter electrode 19 may be a single layer shared between the multiple pixels 10. However, each of the counter electrodes 17, 18, and 19 may be isolated for each pixel.

The following structure may be adopted regardless of whether the case in which each of the counter electrodes 17, 18, and 19 is a single layer or the case in which each of the counter electrodes 17, 18, and 19 is isolated for each pixel is supposed. Specifically, a part of the first counter electrode 17 in a certain pixel 10 arbitrarily selected from the multiple pixels 10 is electrically connected to a part of the first counter electrode 17 in the pixel 10 adjacent to the certain pixel 10. A part of the second counter electrode 18 in a certain pixel 10 arbitrarily selected from the multiple pixels 10 is electrically connected to a part of the second counter electrode 18 in the pixel 10 adjacent to the certain pixel 10. A part of the third counter electrode 19 in a certain pixel 10 arbitrarily selected from the multiple pixels 10 is electrically connected to a part of the third counter electrode 19 in the pixel 10 adjacent to the certain pixel 10.

FIG. 2B illustrates an imaging device 100b having another configuration of the multiple counter electrodes 17, 18, and 19. FIG. 2C illustrates an imaging device 100c having another configuration of the multiple counter electrodes 17, 18, and 19. As illustrated in FIG. 2B and FIG. 2C, the multiple counter electrodes 17, 18, and 19 may have different thicknesses.

For example, as illustrated in FIG. 2B, the second counter electrode 18 may be thicker than the third counter electrode 19. The third counter electrode 19 may be thicker than the first counter electrode 17. In other words, the thickness of the counter electrode may be increased as the counter electrode comes closer to the light incident plane from the semiconductor substrate 1. With this configuration, it is possible to relieve the unevenness of the top face of an insulating layer formed in manufacturing of the imaging device 100.

Alternatively, as illustrated in FIG. 2C, the first counter electrode 17 may be thicker than the third counter electrode 19. The third counter electrode 19 may be thicker than the second counter electrode 18. In other words, the thickness of the counter electrode may be increased as the counter electrode comes closer to the semiconductor substrate 1 from the light incident plane. With this configuration, the photoelectric conversion caused by the incidence of light on the semiconductor substrate 1 may be further suppressed to reduce parasitic sensitivity.

As illustrated in FIG. 2A, an insulating layer 7 is provided between the semiconductor substrate 1 and the first pixel electrode 13. An insulating layer 8 is provided between the third pixel electrode 15 and the first counter electrode 17. An insulating layer 9 is provided between the second pixel electrode 14 and the third counter electrode 19. The insulating layers 7, 8, and 9 are made of an insulating material, such as SiO₂.

The insulating layers 7, 8, and 9 may have different permittivities. For example, the permittivity of the insulating layer 8 and the permittivity of the insulating layer 9 may be lower than the permittivity of the insulating layer 7. This may achieve the advantageous effect to suppress the capacitive coupling between the second pixel electrode 14 and the third pixel electrode 15 and the capacitive coupling between the third pixel electrode 15 and the first pixel electrode 13. In order to differentiate the permittivity, an appropriate material may be selected from SiO₂, SiOF, SiOC, and so on for usage. The permittivity may be differentiated using the same material.

Each pixel 10 further includes multiple plugs 31, 32, and 33. The respective plugs 31, 32, and 33 extend in the normal direction of the semiconductor substrate 1. The multiple plugs 31, 32, and 33 include a first plug 31, a second plug 32, and a third plug 33. The semiconductor substrate 1 is electrically connected to the first pixel electrode 13 with the first plug 31. The semiconductor substrate 1 is electrically connected to the second pixel electrode 14 with the second plug 32. The semiconductor substrate 1 is electrically connected to the third pixel electrode 15 with the third plug 33.

The plugs 31, 32, and 33 are made of a conductive material. The conductive material is, for example, metal, metal oxide, metal nitride, or conductive polysilicon.

The semiconductor substrate 1 includes multiple charge accumulation regions 3, 4, and 5. The charge accumulation regions 3, 4, and 5 may be part of each pixel 10. Each of the charge accumulation regions 3, 4, and 5 is an n-type or p-type impurity region. The multiple charge accumulation regions 3, 4, and 5 include a first charge accumulation region 3, a second charge accumulation region 4, and a third charge accumulation region 5. The first charge accumulation region 3 is electrically connected to the first pixel electrode 13 with the first plug 31. The second charge accumulation region 4 is electrically connected to the second pixel electrode 14 with the second plug 32. The third charge accumulation region 5 is electrically connected to the third pixel electrode 15 with the third plug 33.

The semiconductor substrate 1 may include multiple transistors for reading out the electric charge stored in the charge accumulation regions 3, 4, and 5 and resetting the stored electric charge.

A pair of electron and hole is generated in each of the photoelectric conversion layers 121, 122, and 123 upon irradiation of the imaging device 100 with the light,

For example, upon application of a voltage between the first counter electrode 17 and the first pixel electrode 13 so that the potential of the first counter electrode 17 exceeds the potential of the first pixel electrode 13, the hole, which is the positive electric charge, is collected in the first pixel electrode 13 and the electron, which is the negative electric charge, is collected in the first counter electrode 17. The hole collected in the first pixel electrode 13 is stored in the first plug 31 and the first charge accumulation region 3.

The thickness of the first counter electrode 17 may be different from the thickness of the first pixel electrode 13. The first counter electrode 17 may be thicker than the first pixel electrode 13. Increasing the thickness of the first counter electrode 17 may decrease the resistance value of the first counter electrode 17. This achieves the advantageous effect to suppress a reduction in bias voltage caused of the resistance value of the first counter electrode 17.

Upon application of a voltage between the second counter electrode 18 and the second pixel electrode 14 so that the potential of the second counter electrode 18 exceeds the potential of the second pixel electrode 14, the hole, which is the positive electric charge, is collected in the second pixel electrode 14 and the electron, which is the negative electric charge, is collected in the second counter electrode 18. The hole collected in the second pixel electrode 14 is stored in the second plug 32 and the second charge accumulation region 4.

The thickness of the second counter electrode 18 may be different from the thickness of the second pixel electrode 14. The second counter electrode 18 may be thicker than the second pixel electrode 14. Increasing the thickness of the second counter electrode 18 may decrease the resistance value of the second counter electrode 18. This achieves the advantageous effect to suppress a reduction in bias voltage due to the resistance value of the second counter electrode 18.

Upon application of a voltage between the third counter electrode 19 and the third pixel electrode 15 so that the potential of the third counter electrode 19 exceeds the potential of the third pixel electrode 15, the hole, which is the positive electric charge, is collected in the third pixel electrode 15 and the electron, which is the negative electric charge, is collected in the third counter electrode 19. The hole collected in the third pixel electrode 15 is stored in the third plug 33 and the third charge accumulation region 5.

The thickness of the third counter electrode 19 may be different from the thickness of the third pixel electrode 15. The third counter electrode 19 may be thicker than the third pixel electrode 15. Increasing the thickness of the third counter electrode 19 may decrease the resistance value of the third counter electrode 19. This achieves the advantageous effect to suppress a reduction in bias voltage caused of the resistance value of the third counter electrode 19.

The first counter electrode 17 and the third counter electrode 19 may be composed of a single counter electrode. In other words, the counter electrode may be shared between the first photoelectric conversion layer 121 and the third photoelectric conversion layer 123. Alternatively, the second counter electrode 18 and the third counter electrode 19 may be composed of a single counter electrode. In other words, the counter electrode may be shared between the second photoelectric conversion layer 122 and the third photoelectric conversion layer 123.

A blocking layer may be provided between the pixel electrode and the photoelectric conversion layer to suppress the inflow of the electric charge to the pixel electrode in dark time.

The imaging device 100 of the first embodiment has a multilayer structure. The “multilayer” means that the multiple photoelectric conversion layers exist in the normal direction of the semiconductor substrate 1. Since the areas of the pixel electrodes are sufficiently ensured in the multilayer structure, it is advantageous to improve the sensitivity of the pixels. Since the three photoelectric conversion layers 121, 122, and 123 exist in the first embodiment, the imaging device 100 has a three-layer structure. The photoelectric conversion layers 121, 122, and 123 typically have different photoelectric conversion characteristics.

In the imaging device 100 having the three-layer structure, the three photoelectric conversion layers may include the photoelectric conversion layer having the sensitivity to blue light, the photoelectric conversion layer having the sensitivity to green light, and the photoelectric conversion layer having the sensitivity to red light. Accordingly, the three-layer structure is suitable for forming a full-color image.

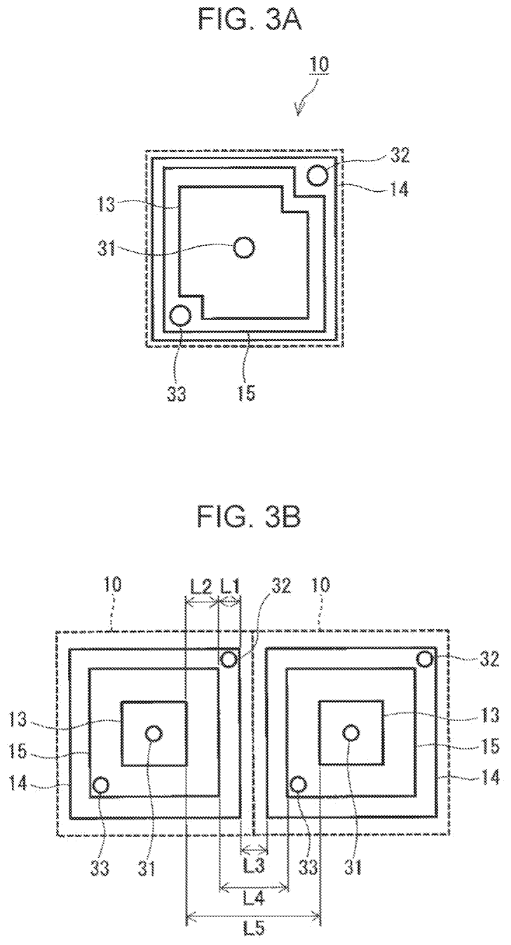

FIG. 3A illustrates how the pixel electrodes 13, 14, and 15 and the plugs 31, 32, and 33 are arranged when the imaging device 100 is viewed from the normal direction of the semiconductor substrate 1. In the first embodiment, the area of the first pixel electrode 13 is smaller than the area of the second pixel electrode 14. With this configuration, even when the light in the first wavelength region (red light) is obliquely incident on a certain pixel 10, the electric charge occurring in the oblique incidence is less likely to be collected in the first pixel electrode 13 because the area of the first pixel electrode 13 is restricted. As a result, the color mixture between the adjacent pixels 10 may be suppressed. In order to suppress the parasitic sensitivity, the first pixel electrode 13 may be decreased in size to an extent in which the light is not excessively incident on the semiconductor substrate 1.

In this specification, viewing the imaging device 100 from the normal direction of the semiconductor substrate 1 is equivalent to a plan view of the imaging device 100.

The area of the third pixel electrode 15 is also smaller than the area of the second pixel electrode 14. With this configuration, even when the light in the third wavelength region (green light) is obliquely incident on a certain pixel 10, the electric charge occurring in the oblique incidence is less likely to be collected in the second pixel electrode 14 because the area of the second pixel electrode 14 is restricted. As a result, the color mixture between the adjacent pixels 10 may be suppressed.

In the first embodiment, the area of the third pixel electrode 15 is smaller than the area of the second pixel electrode 14 and the area of the first pixel electrode 13 is smaller than the area of the third pixel electrode 15. With this configuration, both the advantageous effect achieved when the area of the first pixel electrode 13 is smaller than the area of the second pixel electrode 14 and the advantageous effect achieved when the area of the third pixel electrode 15 is smaller than the area of the second pixel electrode 14 are achieved.

In the first embodiment, the area of the pixel electrode is decreased with the decreasing distance to the semiconductor substrate 1. The color mixture caused by the oblique incidence is likely to occur as the pixel electrode is more apart from the outermost surface of the imaging device 100. Accordingly, the relationship in the area between the first pixel electrode 13, the third pixel electrode 15, and the second pixel electrode 14 in the first embodiment produces a highly advantageous effect.

The imaging device 100 of the first embodiment does not include microlenses. The influence of the light that is obliquely incident is reduced by the configuration of the pixel electrodes 13, 14, and 15. Accordingly, the problem of the color mixture between the adjacent pixels 10 is less likely to be obvious even without the microlens.

In this specification, the area of the pixel electrode means the area of each pixel electrode when the imaging device 100 is viewed from the normal direction of the semiconductor substrate 1. In other words, the area of the pixel electrode is equal to the area of a projection image obtained by orthogonally projecting the pixel electrode on a plane perpendicular to the normal direction of the semiconductor substrate 1.

As illustrated in FIG. 3A, when the imaging device 100 is viewed from the normal direction of the semiconductor substrate 1, the first pixel electrode 13 is within the outer edge of the second pixel electrode 14. Specifically, the entire first pixel electrode 13 is within the outer edge of the second pixel electrode 14. With this configuration, it is possible to suppress the color mixture caused by the oblique incidence more sufficiently.

Similarly, when the imaging device 100 is viewed from the normal direction of the semiconductor substrate 1, the third pixel electrode 15 is within the outer edge of the second pixel electrode 14. Specifically, the entire third pixel electrode 15 is within the outer edge of the second pixel electrode 14. With this configuration, it is possible to suppress the color mixture caused by the oblique incidence more sufficiently.

In the first embodiment, the first pixel electrode 13 is within the outer edge of the third pixel electrode 15. With this configuration, both the advantageous effect achieved when the first pixel electrode 13 is within the outer edge of the second pixel electrode 14 and the advantageous effect achieved when the third pixel electrode 15 is within the outer edge of the second pixel electrode 14 are achieved.

FIG. 3B illustrates another arrangement of the pixel electrodes 13, 14, and 15 when the imaging device 100 is viewed from the normal direction of the semiconductor substrate 1. In a direction parallel to the surface of the semiconductor substrate 1, the distance between the outer edge of the first pixel electrode 13 and the outer edge of the third pixel electrode 15 is indicated by a distance L2. In the direction perpendicular to the normal direction of the semiconductor substrate 1, the distance between the outer edge of the second pixel electrode 14 and the outer edge of the third pixel electrode 15 is indicated by a distance L1. The distance L2 is greater than the distance L1. The first pixel electrode 13 is positioned on the bottom layer and is more likely to be affected by the oblique incidence than the third pixel electrode 15. Accordingly, adjusting the sizes of the pixel electrodes 13, 14, and 15 so as to meet the relationship of the distance L2>the distance L1 enables the color mixture caused by the oblique incidence to be significantly suppressed. The “distance” represents the shortest distance.

In the example illustrated in FIG. 3B, each of the first pixel electrode 13 and the third pixel electrode 15 has no cutout. The second plug 32 extends in the normal direction of the semiconductor substrate 1 at a position outside the first pixel electrode 13 and the third pixel electrode 15. The third plug 33 extends in the normal direction of the semiconductor substrate 1 at a position outside the first pixel electrode 13. The presence of the cutout is not particularly restricted.

In the example illustrated in FIG. 33, the pixel electrodes 13, 14, and 15 each have a rectangular shape in a plan view. All the four sides composing the outer edge of the second pixel electrode 14 are apart from the outer edge of the third pixel electrode 15 by the distance L1. All the four sides composing the outer edge of the third pixel electrode 15 are apart from the outer edge of the first pixel electrode 13 by the distance L2. In other words, the pixel electrodes exhibit an isotropic reduction in size. With this configuration, it is possible to suppress the influence of the oblique incidence in all directions. In addition, the advantageous effect to suppress the capacitive coupling between the pixel electrodes in the adjacent pixels 10 is achieved maximally.

In the example illustrated in FIG. 3B, the pixel electrodes 13, 14, and 15 each have a square shape. The centroids of the first pixel electrode 13, the second pixel electrode 14, and the third pixel electrode 15 coincide with each other. The first pixel electrode 13, the second pixel electrode 14, and the third pixel electrode 15 are similar to each other.

The distance between the first pixel electrodes 13 in the adjacent pixels 10 is indicated by a distance L5. The distance between the second pixel electrodes 14 in the adjacent pixels 10 is indicated by a distance L3. The distance between the third pixel electrodes 15 in the adjacent pixels 10 is indicated by a distance L4. The relationship of the distance L3<the distance L4 is met. The relationship of the distance L4<the distance L5 is met. With this configuration, it is possible to sufficiently suppress the capacitive coupling between the pixel electrodes on the lower layers.

In the first embodiment, the material of the first pixel electrode 13 is different from the material of the second pixel electrode 14. Since the second pixel electrode 14 is positioned on the top layer, the transparent electrode is used as the second pixel electrode 14. In contrast, since the first pixel electrode 13 is positioned on the bottom layer, the first pixel electrode 13 may not be the transparent electrode. When the first pixel electrode 13 is made of a light-shielding material, the incidence of light on the semiconductor substrate 1 is capable of being inhibited with the first pixel electrode 13. As a result, the photoelectric conversion caused by the incidence of light on the semiconductor substrate 1 is suppressed to reduce the parasitic sensitivity.

The light-shielding material is, for example, metal or conductive metal compound. The metal is, for example, tungsten or titanium. The conductive metal compound is, for example, metal nitride, such as titanium nitride.

The material of the first pixel electrode 13 may be different from the material of the third pixel electrode 15. The third pixel electrode 15 may be the transparent electrode. The first pixel electrode 13 may be the non-transparent electrode. With this configuration, the photoelectric conversion caused by the incidence of light on the semiconductor substrate 1 may be further suppressed to reduce the parasitic sensitivity.

### (First Modification)

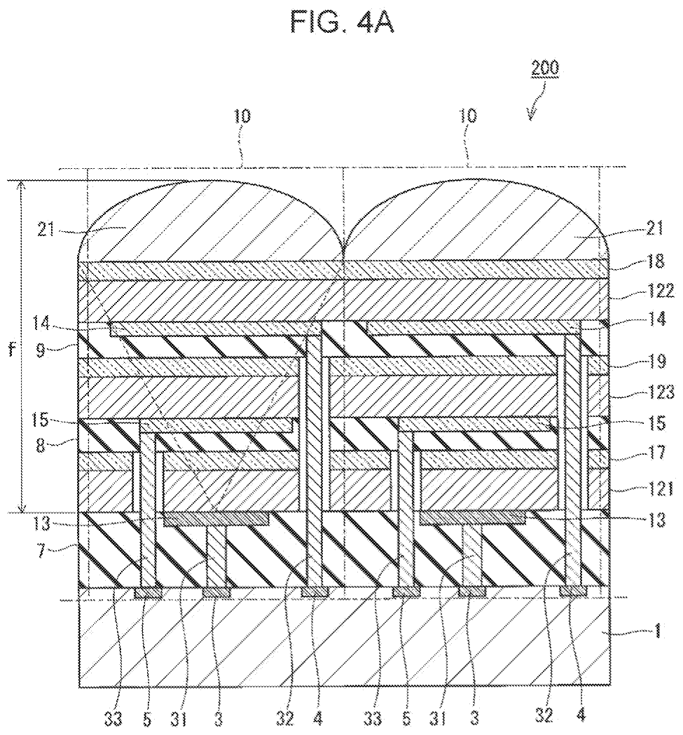

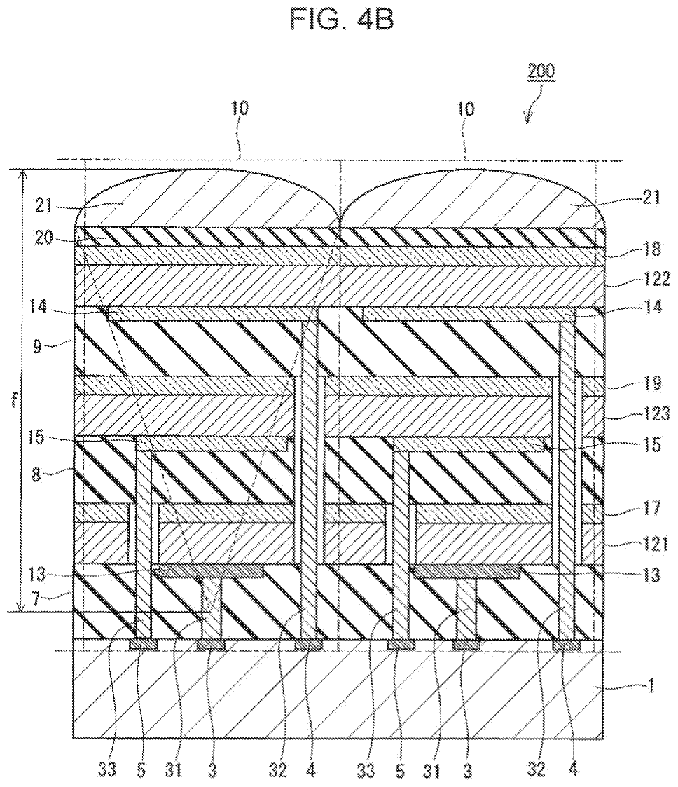

FIG. 4A illustrates a cross section of an imaging device 200 according to a first modification. Each pixel 10 in the imaging device 200 further includes a microlens 21, in addition to the components in the imaging device 100 described above with reference to FIG. 2A. The microlenses 21 are arranged above the semiconductor substrate 1 so as to compose the surface of the imaging device 200. In the first modification, the microlenses 21 are arranged above the second photoelectric conversion layer 122. The light itself that is obliquely incident is capable of being reduced with the microlenses 21. The advantageous effect achieved by the microlenses 21 is coupled with the advantageous effect achieved by restriction of the areas of the pixel electrodes to suppress the color mixture caused by the oblique incidence more sufficiently.

As illustrated in FIG. 4A, the microlens 21 may be focused on the first pixel electrode 13.

FIG. 4B illustrates a cross section of another imaging device 200 according to the first modification. As illustrated in FIG. 4B, the focus of the microlens 21 may be shifted to a point below the first pixel electrode 13. In the example illustrated in FIG. 4B, the focus of the microlens 21 is between the bottom face of the first pixel electrode 13 and the top face of the semiconductor substrate 1. When the focus of the microlens 21 is shifted to a point below the first pixel electrode 13, the area where the light condensed by the microlens 21 passes through may be within the outer edge of the first pixel electrode 13. This suppresses an occurrence of the electric charge caused by the incidence of light on the semiconductor substrate 1. Referring to FIG. 4A and FIG. 4B, broken lines indicate the path of the condensed light. The point of intersection of the broken lines indicates the focus.

In this specification, the position of the focus can be determined by a focal length f of the microlens 21. The focal length f of the microlens 21 is represented by Equation (1). In Equation (1), R denotes the radius of curvature of the microlens 21, n1 denotes the refraction index of the material of the microlens 21, and n0 denotes the refraction index of the medium that is in contact with the microlens 21 at the light incident side. Equation (1) represents the focal length f of the microlens 21 when the light is incident on the microlens 21 having the refraction index n1 and the radius of curvature R from the medium having the refraction index n0 (for example, air space).

f={n1/(n1−n0)}R (1)

As illustrated in FIG. 4B, an insulating layer 20 may be provided between the second counter electrode 18 and the microlenses 21.

### (Second Modification)

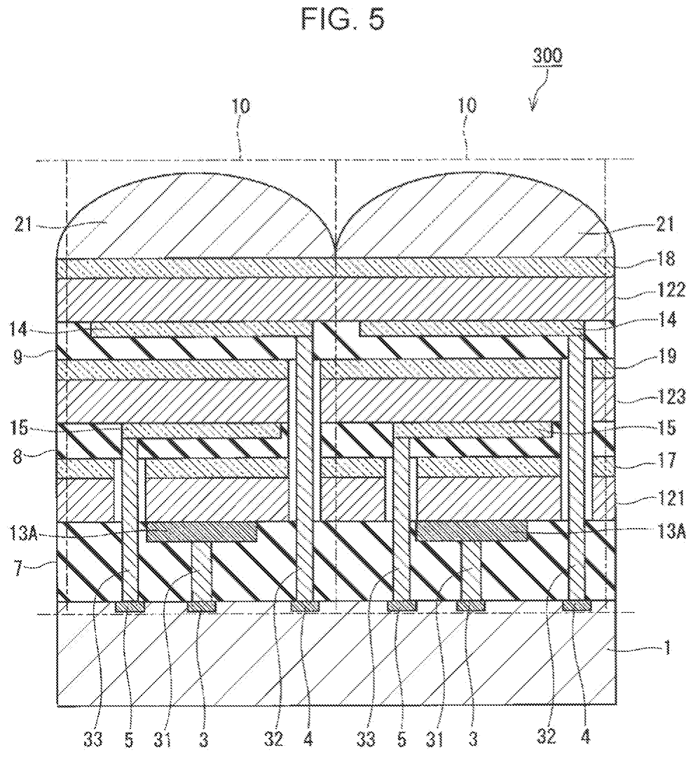

FIG. 5 illustrates a cross section of an imaging device 300 according to a second modification. The imaging device 300 includes a thick first pixel electrode 13A. Specifically, the first pixel electrode 13A is thicker than the second pixel electrode 14. With this configuration, the incidence of light on the semiconductor substrate 1 is capable of being prevented because it is difficult for the light to transmit through the first pixel electrode 13A. As a result, the photoelectric conversion caused by the incidence of light on the semiconductor substrate 1 may be further suppressed to reduce the parasitic sensitivity.

The first pixel electrode 13A is thicker than the third pixel electrode 15. With this configuration, the incidence of light on the semiconductor substrate 1 is capable of being sufficiently suppressed because it is difficult for the light to transmit through the first pixel electrode 13A. As a result, the photoelectric conversion caused by the incidence of light on the semiconductor substrate 1 may be further suppressed to reduce the parasitic sensitivity.

Typically, the second pixel electrode 14 is formed so as to have the same thickness as that of the third pixel electrode 15, and the first pixel electrode 13A is formed so as to be thicker than the second pixel electrode 14 and the third pixel electrode 15.

The thickness of the pixel electrode can be determined by the following method. A cross section parallel to the normal direction of the semiconductor substrate 1 is formed. The cross section is observed using an electron microscope (for example, a scanning electron microscope). The thickness of he pixel electrode is measured at multiple arbitrary positions (for example, five positions) included in the generated image. The average of the measured values is determined to be the thickness of the pixel electrode. The “thickness” is the dimension in a direction parallel to the normal direction of the semiconductor substrate 1. The thickness of the counter electrode can be determined using the same method as in the pixel electrode.

### (Third Modification)

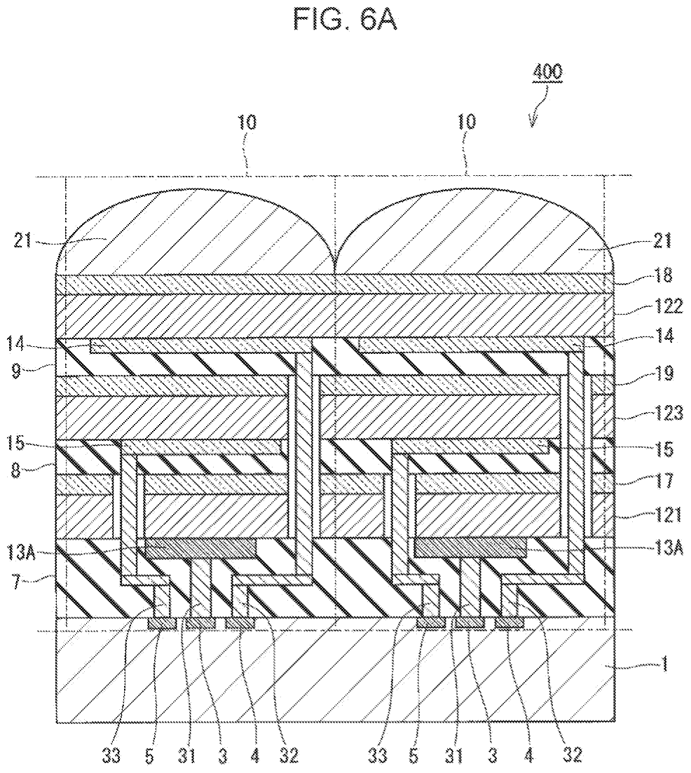

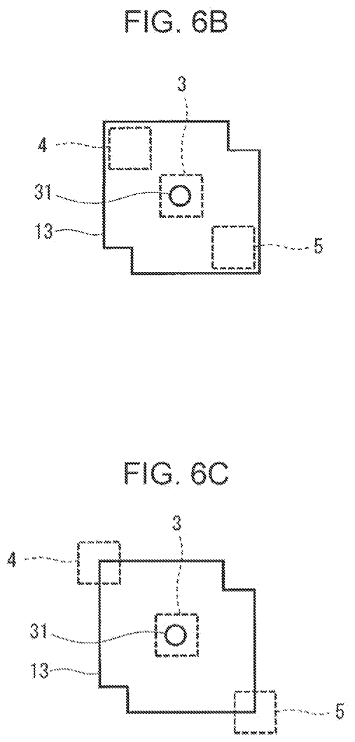

FIG. 6A illustrates a cross section of an imaging device 400 according to a third modification. FIG. 6B illustrates how the first charge accumulation region 3, the second charge accumulation region 4, the third charge accumulation region 5, and the first pixel electrode 13 are arranged when the imaging device 400 is viewed from the normal direction of the semiconductor substrate 1.

As illustrated in FIG. 6A, in the third modification, the second plug 32 and the third plug 33 are made close to the first plug 31 via a wiring layer between the first pixel electrode 13A (or the first pixel electrode 13) and the semiconductor substrate 1.

In the imaging device in the related art, the photoelectric converters are supported by the semiconductor substrate. Upon incidence of light on the semiconductor substrate, the photoelectric conversion occurs in the semiconductor substrate. A reduction of the parasitic sensitivity of the semiconductor substrate is beneficial to improvement of the image quality.

As illustrated in FIG. 6B, according to the third modification, when the imaging device 400 is viewed from the normal direction of the semiconductor substrate 1, the first charge accumulation region 3 and the second charge accumulation region 4 are overlapped with the first pixel electrode 13. Specifically, the first charge accumulation region 3, the second charge accumulation region 4, and the third charge accumulation region 5 are overlapped with the first pixel electrode 13. With this configuration, since the light is blocked by the first pixel electrode 13, the light is less likely to be incident on each charge accumulation region. As a result, it is possible to reduce the parasitic sensitivity of the semiconductor substrate 1

FIG. 6C illustrates another arrangement of the first charge accumulation region 3, the second charge accumulation region 4, the third charge accumulation region 5, and the first pixel electrode 13. As illustrated in FIG. 6C, only part of the second charge accumulation region 4 may be overlapped with the first pixel electrode 13. Only part of the third charge accumulation region 5 may be overlapped with the first pixel electrode 13. Also with this configuration, the advantageous effect to prevent the second charge accumulation region 4 and the third charge accumulation region 5 from being irradiated with the light that is obliquely incident is achieved.

### (Other Modifications)

The pixel electrodes may be electrically connected to the charge accumulation regions via the plugs through the semiconductor substrate and the wiring layer at the lower side of the semiconductor substrate.

The above description of the first embodiment is applicable to not only the imaging devices 100, 200, 300, and 400 having the three-layer structure but also an imaging device having a two-layer structure. The third photoelectric conversion layer 123, the third pixel electrode 15, the third plug 33, and the third charge accumulation region 5 may be arbitrary elements. When the description of the first embodiment is applied to the imaging device having the two-layer structure, the description of the third photoelectric conversion layer 123, the third pixel electrode 15, the third plug 33, and the third charge accumulation region 5 is excluded.

### Second Embodiment

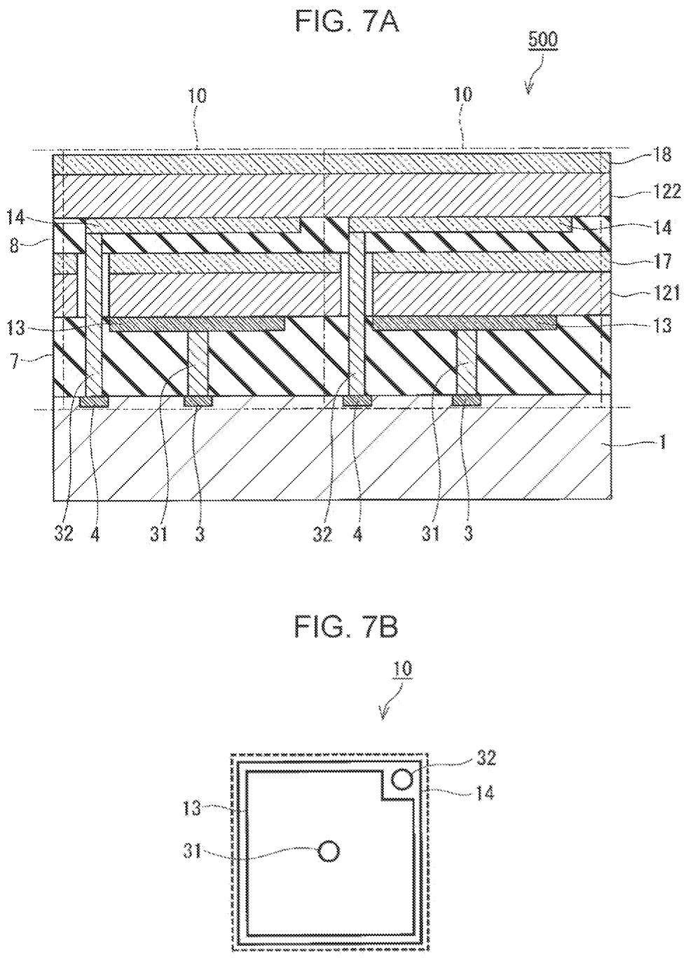

FIG. 7A illustrates a cross section of an imaging device 500 according to a second embodiment. FIG. 7B illustrates how the pixel electrodes 13 and 14 and the plugs 31 and 32 are arranged when the imaging device 500 is viewed from the normal direction of the semiconductor substrate 1. The imaging device 500 has the two-layer structure.

The first photoelectric conversion layer 121 has the sensitivity to, for example, the wavelength region of the near-infrared light. The first photoelectric conversion layer 121 may be manufactured using a photoelectric conversion material having the sensitivity to the wavelength region of the near-infrared light. The second photoelectric conversion layer 122 has the sensitivity to, for example, the wavelength region of the visible light. The second photoelectric conversion layer 122 may be manufactured using a photoelectric conversion material having the sensitivity to the wavelength region of the visible light. A color filter may be provided above the second photoelectric conversion layer 122. The imaging device 500 may include the microlenses.

The area of the first pixel electrode 13 is smaller than the area of the second pixel electrode 14 also in the imaging device 500 of the second embodiment. Accordingly, also with the imaging device 500 of the second embodiment, the same advantageous effects as in the imaging devices 100, 200, 300, and 400 described above are achieved.

### Third Embodiment

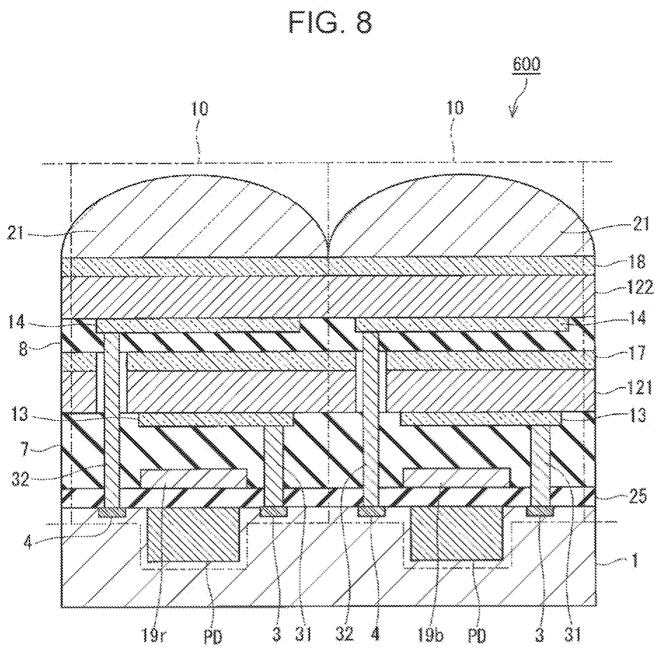

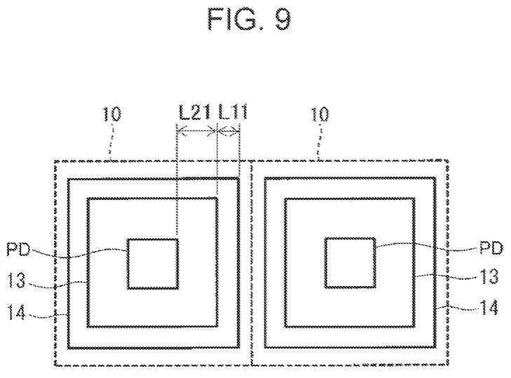

FIG. 8 illustrates a cross section of an imaging device 600 according to a third embodiment. Each pixel 10 includes a photodiode PD, in addition to the first photoelectric conversion layer 121 and the second photoelectric conversion layer 122. The photodiode PD is provided in the semiconductor substrate 1. Each of the first pixel electrode 13 and the second pixel electrode 14 has the light transmittance. A color filter 19r or a color filter 19b is provided between the photodiode PD and the first photoelectric conversion layer 121. Each photodiode PD is covered with the color filter 19r or the color filter 19b. An insulating layer 25 is provided between the photodiodes PD and the color filters 19r and 19b. The insulating layer 25 is made of an insulating material, such as SiO₂. The insulating layer 7 exists between the first pixel electrodes 13 and the color filters 19r and 19b. The insulating layer 7 also functions as a planarization layer and may be made of transparent resin, such as acrylic resin or epoxy resin. The imaging device 600 includes the microlenses 21. The light is capable of being effectively led to the photodiodes PD owing to the function of the microlenses 21.

The first photoelectric conversion layer 121 has the sensitivity to, for example, the wavelength region of green light. The first photoelectric conversion layer 121 may be manufactured using the photoelectric conversion material having the sensitivity to the wavelength region of green light. The second photoelectric conversion layer 122 has the sensitivity to, for example, the wavelength region of the near-infrared light. The second photoelectric conversion layer 122 may be manufactured using the photoelectric conversion material having the sensitivity to the wavelength region of the near-infrared light. The photodiode PD is typically a silicon photodiode. The color filter 19r is a filter that cuts red light. The color filter 19b is a filter that cuts blue light.

Since the first photoelectric conversion layer 121 has the sensitivity to the wavelength region of green light and the second photoelectric conversion layer 122 has the sensitivity to the wavelength region of the near-infrared light, red light and blue light reach the color filters 19r and 19b. Red light is cut by the color filter 19r and only blue light is incident on the photodiode PD. Blue light is cut by the color filter 19b and only red light is incident on the photodiode PD. Accordingly, the imaging device 600 is capable of generating an image based on the near-infrared light and a full-color image.

FIG. 9 illustrates how the pixel electrodes 13 and 14 and the photodiodes PD are arranged when the imaging device 600 is viewed from the normal direction of the semiconductor substrate 1. The area of the first pixel electrode 13 is smaller than the area of the second pixel electrode 14. The area of a light-sensing portion of the photodiode PD is smaller than the area of the first pixel electrode 13. The first pixel electrode 13 is within the outer edge of the second pixel electrode 14. The light-sensing portion of the photodiode PD is within the outer edge of the first pixel electrode 13.

The area of the first pixel electrode 13 is smaller than the area of the second pixel electrode 14 also in the imaging device 600 of the third embodiment. Accordingly, also with the imaging device 600 of the third embodiment, the same advantageous effects as in the imaging devices 100, 200, 300, 400, and 500 described above are achieved,

In the direction perpendicular to the normal direction of the semiconductor substrate 1, the distance between the outer edge of the light-sensing portion of the photodiode PD and the outer edge of the first pixel electrode 13 is denoted by a distance L21. In the direction perpendicular to the normal direction of the semiconductor substrate 1, the distance between the outer edge of the first pixel electrode 13 and the outer edge of the second pixel electrode 14 is denoted by a distance L11. The distance L21 is greater than the distance L11. The photodiodes PD are provided in the semiconductor substrate 1 and are more likely to be affected by the oblique incidence than the first pixel electrode 13. Accordingly, adjusting the sizes of the light-sensing portion of the photodiode PD, the first pixel electrode 13, and the second pixel electrode 14 so as to meet the relationship of the distance L21>the distance L11 enables the color mixture caused by the oblique incidence to be significantly suppressed.

When the light-sensing portion of the photodiode PD has a small area, the distance between the photodiodes PD in the adjacent pixels 10 is sufficiently ensured. In this case, the coupling between the photodiodes PD is capable of being suppressed. Since the photodiodes PD in the adjacent pixels 10 generate the electric charge corresponding to different colors (red and glue in the third embodiment), the color mixture may occur if the coupling occurs. Accordingly, the suppression of the coupling between the photodiodes PD in the adjacent pixels 10 is meaningful.

### Fourth Embodiment

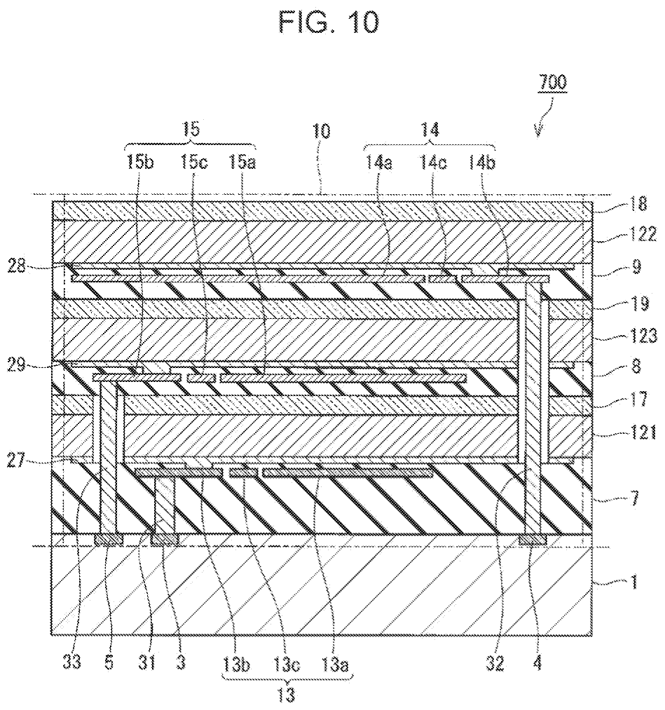

FIG. 10 illustrates a cross section of an imaging device 700 according to a fourth embodiment of the present disclosure. The imaging device 700 differs from the imaging devices described above in the structure of the electrodes. In the imaging device 700, the first pixel electrode 13 includes a first storage electrode 13a, a first readout electrode 13b, and a first transfer electrode 13c. The second pixel electrode 14 includes a second storage electrode 14a, a second readout electrode 14b, and a second transfer electrode 14c. The third pixel electrode 15 includes a third storage electrode 15a, a third readout electrode 15b, and a third transfer electrode 15c. The transfer electrodes 13c, 14c, and 15c may be omitted.

A first semiconductor layer 27 is provided between the first pixel electrode 13 and the first photoelectric conversion layer 121. A part of the insulating layer 7 exists between the first semiconductor layer 27 and the first pixel electrode 13. A second semiconductor layer 28 is provided between the second pixel electrode 14 and the second photoelectric conversion layer 122. A part of the insulating layer 9 exists between the second semiconductor layer 28 and the second pixel electrode 14. A third semiconductor layer 29 is provided between the third pixel electrode 15 and the third photoelectric conversion layer 123. A part of the insulating layer 8 exists between the third semiconductor layer 29 and the third pixel electrode 15. The semiconductor layers 27, 28, and 29 are provided to perform the storage of the electric charge more efficiently and are made of a semiconductor material having the light transmittance.

The first storage electrode 13a and the first transfer electrode 13c are opposed to the first photoelectric conversion layer 121 via a part of the insulating layer 7 or via a part of the insulating layer 7 and the first semiconductor layer 27. At least part of the first readout electrode 13b is in contact with the first photoelectric conversion layer 121 directly or via the first semiconductor layer 27. The first plug 31 is connected to the first readout electrode 13b. The first storage electrode 13a, the first readout electrode 13b, and the first transfer electrode 13c are electrically connected to lines (not illustrated). Desired voltage may be applied to each of the first storage electrode 13a, the first readout electrode 13b, and the first transfer electrode 13c. The first storage electrode 13a may function as a charge storage electrode for attracting the electric charge occurring in the first photoelectric conversion layer 121 and storing the electric charge in the first photoelectric conversion layer 121 in accordance with the applied voltage. In a plan view of the imaging device 700, the first transfer electrode 13c is arranged between the first storage electrode 13a and the first readout electrode 13b. The first transfer electrode 13c has a role to hold the stored electric charge and control the transfer of the electric charge. Control of the voltage applied to the first storage electrode 13a, the first readout electrode 13b, and the first transfer electrode 13c enables the electric charge occurring in the first photoelectric conversion layer 121 to be stored in the first photoelectric conversion layer 121 or on the boundary face of the first photoelectric conversion layer 121 and enables the electric charge occurring in the first photoelectric conversion layer 121 to be extracted to the first charge accumulation region 3. The above description about the first pixel electrode 13 is applicable to the second pixel electrode 14 and the third pixel electrode 15 by replacing the “first” with the “second” or the “third”.

According to the fourth embodiment, each of the first pixel electrode 13, the second pixel electrode 14, and the third pixel electrode 15 is divided into multiple portions. In this case, the “area of the pixel electrode” means the total of the areas of the multiple portions. The magnitude relationship of the pixel area may be applied to each of the storage electrode and the readout electrode. Specifically, the area of the first readout electrode 13b may be smaller than the area of the third readout electrode 15b, and the area of the third readout electrode 15b may be smaller than the area of the second readout electrode 14b. The area of the first storage electrode 13a may be smaller than the area of the third storage electrode 15a and the area of the third storage electrode 15a may be smaller than the area of the second storage electrode 14a.

With the structure of the electrodes of the fourth embodiment, it is possible to efficiently collect and transfer the electric charge occurring in the photoelectric conversion layers to improve the sensitivity. The structure of the electrodes of the fourth embodiment is applicable to all the embodiments described above.

The technique disclosed in this specification is useful for the imaging device. The imaging device is applicable to an imaging apparatus, an optical sensor, and so on. The imaging apparatus is, for example, a digital camera, a medical camera, a monitoring camera, a robot camera, or a vehicle camera.

What is claimed is:

1. An imaging device comprising:
a plurality of pixels, wherein
each of the plurality of pixels includes
a first photoelectric conversion layer that converts light into first electric charge,
a first pixel electrode that collects the first electric charge,
a second photoelectric conversion layer that is arranged above the first photoelectric conversion layer and that converts light into second electric charge, and
a second pixel electrode that collects the second electric charge, and
an area of the first pixel electrode is smaller than an area of the second pixel electrode.

2. The imaging device according to claim 1, further comprising:
a semiconductor substrate,
wherein the first pixel electrode is within an outer edge of the second pixel electrode when the imaging device is viewed from a normal direction of the semiconductor substrate.

3. The imaging device according to claim 1,
wherein a material of the first pixel electrode is different from a material of the second pixel electrode.

4. The imaging device according to claim 1,
wherein the first pixel electrode is thicker than the second pixel electrode.

5. The imaging device according to claim 1, further comprising:
a semiconductor substrate;
a first charge accumulation region that is provided in the semiconductor substrate and that is electrically connected to the first pixel electrode; and
a second charge accumulation region that is provided in the semiconductor substrate and that is electrically connected to the second pixel electrode,
wherein the first charge accumulation region and the second charge accumulation region are overlapped with the first pixel electrode when the imaging device is viewed from a normal direction of the semiconductor substrate,

6. The imaging device according to claim 1, further comprising:
a third photoelectric conversion layer that is arranged between the first photoelectric conversion layer and the second photoelectric conversion layer and that converts light into third electric charge; and
a third pixel electrode that collects the third electric charge.

7. The imaging device according to claim 6,
wherein an area of the third pixel electrode is smaller than the area of the second pixel electrode.

8. The imaging device according to claim 6,
wherein the area of the first pixel electrode is smaller than an area of the third pixel electrode.

9. The imaging device according to claim 6, further comprising:
a semiconductor substrate,
wherein the third pixel electrode is within an outer edge of the second pixel electrode when the imaging device is viewed from a normal direction of the semiconductor substrate.

10. The imaging device according to claim 6, further comprising:
a semiconductor substrate,
wherein the first pixel electrode is within an outer edge of the third pixel electrode when the imaging device is viewed from a normal direction of the semiconductor substrate.

11. The imaging device according to claim 6,
wherein a material of the first pixel electrode is different from a material of the third pixel electrode.

12. The imaging device according to claim 6,
wherein the first pixel electrode is thicker than the third pixel electrode.

13. The imaging device according to claim 6, further comprising:
a semiconductor substrate;
a first charge accumulation region that is provided in the semiconductor substrate and that is electrically connected to the first pixel electrode;
a second charge accumulation region that is provided in the semiconductor substrate and that is electrically connected to the second pixel electrode; and
a third charge accumulation region that is provided in the semiconductor substrate and that is electrically connected to the third pixel electrode,
wherein the first charge accumulation region, the second charge accumulation region, and the third charge accumulation region are overlapped with the first pixel electrode when the imaging device is viewed from a normal direction of the semiconductor substrate.

14. The imaging device according to claim 6, further comprising:
a semiconductor substrate,
wherein a distance between an outer edge of the first pixel electrode and an outer edge of the third pixel electrode is longer than a distance between an outer edge of the second pixel electrode and the outer edge of the third pixel electrode in a direction parallel to a surface of the semiconductor substrate.

15. The imaging device according to claim 1, wherein
the plurality of pixels include a first pixel, a second pixel, a third pixel adjacent to the first pixel, and a fourth pixel adjacent to the second pixel,
a part of the first photoelectric conversion layer in a first pixel is electrically connected to a part of the first photoelectric conversion layer in the third pixel, and
a part of the second photoelectric conversion layer in a second pixel is electrically connected to a part of the second photoelectric conversion layer in the fourth pixel.

16. The imaging device according to claim 1, further comprising:
a semiconductor substrate, wherein
the first pixel electrode includes a first storage electrode that stores the first electric charge in the first photoelectric conversion layer and a first readout electrode that is electrically connected to the semiconductor substrate, and
the second pixel electrode includes a second storage electrode that stores the second electric charge in the second photoelectric conversion layer and a second readout electrode that is electrically connected to the semiconductor substrate.
